(19) United States
(12) Patent Application Publication
(10) Pub. No.: US 2018/0191299 A1
(43) Pub. Date: Jul. 5, 2018

(54) DIRECTLY-HEATING OVEN CONTROLLED CRYSTAL OSCILLATOR

(71) Applicant: GUANGDONG DAPU TELECOM TECHNOLOGY CO., LTD., Guangdong (CN)

(72) Inventors: Yifeng WANG, Guangdong (CN); Chaosheng LIU, Guangdong (CN)

(73) Assignee: GUANGDONG DAPU TELECOM TECHNOLOGY CO., LTD., Guangdong (CN)

(21) Appl. No.: 15/740,273

(22) PCT Filed: Jul. 27, 2015
(86) PCT No.: PCT/CN2015/085205

§ 371 Date: Dec. 27, 2017

(51) Int. Cl. H03B 5/04; H03H 9/19; H03H 9/02; H03B 5/32

(52) U.S. Cl. CPC H03B 5/04; H03B 5/32; H03H 9/02102; H03H 9/19

(57) ABSTRACT

The present disclosure relates to the technical field of quartz crystal oscillators, and particularly, to a directly-heating oven controlled crystal oscillator. The surface of a wafer is provided with wires, two ends of each wire are respectively connected to one ends of support columns located inside a mounting space, and the other ends of the support columns located outside the mounting space are connected to a crystal pin. Accordingly, the wires on the surface of the wafer are connected to an external circuit by means of the support columns and the crystal pins, and the wires generate heat to heat the wafer after the wires are given a current by the external circuit.

### TECHNICAL FIELD

The present disclosure relates to a technical field of quartz crystal oscillators, and in particular, to a directly-heating oven controlled crystal oscillator.

### BACKGROUND

Quartz crystal oscillators, which are oscillators with high precision and high stability, are widely applied to various oscillating circuits such as color TVs, computers and remote control, etc., and are used for frequency generators in communication systems, and are applied to generate clock signals for data processing devices and provide reference signals for specific systems. A quartz crystal oscillator is a resonating device manufactured utilizing the piezoelectric effect of quartz crystal (that is, a crystalline of silicon dioxide), and has a basic construction substantially as follows: a sheet is cut off from a piece of quartz crystal in a certain azimuth angle (wafer for short, which may be a square, a rectangle or a circle, etc.), a silver layer is coated on its two opposite sides to form electrodes, a lead is soldered to each electrode respectively to connect to a base pin, and an encapsulation shell is added, so that a quartz crystal resonator is constructed, and it is referred to as a quartz crystal, crystal or crystal resonator for short. The products thereof are generally encapsulated with metal shells, or encapsulated with glass shells, ceramic glass shells or plastic shells.

Oven controlled crystal oscillator referred to as OCXO for short is a crystal oscillator that keeps the temperature of the quartz crystal resonator in the crystal oscillator constant by means of a thermostatic bath and minimizes the variation of the output frequency of the oscillator caused by the change of ambient temperature.

The wafer inside the oven controlled crystal oscillator needs to be heated. At present, in the industry, the wafer inside the oven controlled crystal oscillator is often heated in an indirectly-heating manner. As shown in FIG. 1 and FIG. 2, FIG. 1 and FIG. 2 show heating for a wafer inside an oven controlled crystal oscillator in the prior art. It may be seen from FIGS. 1 and FIG. 2 that, in the heating mode for a wafer inside an existing oven controlled crystal oscillator, a heating-related component needs to be assembled inside the oven controlled crystal oscillator. In the heating mode as shown in FIG. 1, it provides a T0-8 base 10, a ceramic substrate 11 (on which a heating circuit is provided), a T0-8 upper cover 12, an insulating ring 13, a metal housing 14 and a quartz wafer 15; in the heating mode as shown in FIG. 2, it provides a T0-8 base 20, a support column 21, a ceramic substrate 23 (on which a control circuit is provided), a heat-generating device 24, a quartz wafer 25 and a T0-8 upper cover 22.

In the heating mode for the wafer inside the existing oven controlled crystal oscillator, a heating-related component needs to be assembled inside the oven controlled crystal oscillator, and high power consumption is necessary because the wafer is heated indirectly.

### SUMMARY

In view of this, the present disclosure provides an oven controlled crystal oscillator in which no complex assembling is required therein and the heating power consumption can be lowered.

The solutions of the disclosure are provided below.

A directly-heating oven controlled crystal oscillator, which includes an upper cover, a base and a wafer, the upper cover is connected with the base to form a mounting space of the wafer, at least two support columns penetrating through the base are provided on the base, one ends of the support columns located inside the mounting space are connected to and support the wafer, and the other ends of the support columns located outside the mounting space are connected to crystal pins, and the surface of the wafer is provided with a wire, where one end of the wire is connected to the one end of one of the support columns located inside the mounting space, and the other end of the wire is connected to the one end of the other of the support columns located inside the mounting space.

Preferably, the wire is made of a platinum material.

Preferably, the number of the wires is two, and each of the two wires has a first wire end and a second wire end far from the first wire end, the first wire ends of the two wires are connected to the one end of one of the support columns located inside the mounting space, and the second wire ends of the two wires are connected to the one end of the other of the support columns located inside the mounting space.

Preferably, the wafer has a lower wafer surface close to the base and an upper wafer surface away from the base, and the two wires are both located on the upper wafer surface.

Preferably, the wafer has a lower wafer surface close to the base and an upper wafer surface away from the base, and the two wires are both located on the lower wafer surface.

Preferably, the wafer has a lower wafer surface close to the base and an upper wafer surface away from the base, and the two wires are respectively located on the lower wafer surface and the upper wafer surface.

Preferably, the surface of the wafer is further provided with a temperature-measuring device, the temperature-measuring device is electrically connected with one end of the support column located inside the mounting space, and the support column connected with the temperature-measuring device is different from the support column connected with the wire.

Preferably, the temperature-measuring device is a temperature sensor or a thermistor.

The disclosure has the beneficial effects below:

The oven controlled crystal oscillator according to the disclosure includes an upper cover, a base and a wafer, the upper cover is connected with the base to form a mounting space of the wafer, at least two support columns penetrating through the base are provided on the base, one ends of the support columns located inside the mounting space are connected to and support the wafer, and the other ends of the support columns located outside the mounting space are connected to a crystal pin, the surface of the wafer is provided with a wire, and one end of the wire is connected to the one end of one of the support columns located inside the mounting space, and the other end of the wire is connected to the one end of the other of the support columns located inside the mounting space. In the disclosure, a surface of the wafer is provided with a wire, two ends of the wire are connected to the one ends of the support columns located inside the mounting space, respectively, and the other end of the support column located outside the mounting space is connected to a crystal pin. Accordingly, the wire on the surface of the wafer is connected to an external circuit by means of the support columns and the crystal pin, and after the wire is given a current by the external circuit, the wire generates heat to heat the wafer. In the oven controlled crystal oscillator according to the disclosure, no additional wafer-heating component needs to be assembled inside the crystal oscillator, and the wafer can be heated just by arranging a wire on the surface of the wafer in one time; moreover, because the wire heats the wafer in a direct-contact manner, waste of heating power consumption will be avoided, thereby lowering the heating power consumption of the wafer on the whole.

### BRIEF DESCRIPTION OF THE DRAWINGS

FIG. 1 is a schematic diagram showing the heating for a wafer inside an oven controlled crystal oscillator of the prior art;

FIG. 2 is another schematic diagram showing the heating for a wafer inside an oven controlled crystal oscillator of the prior art;

FIG. 3 is a sectional view of a directly-heating oven controlled crystal oscillator according to the disclosure;

FIG. 4 is a top view of a wafer in a directly-heating oven controlled crystal oscillator according to the disclosure; and

FIG. 5 is a top view of a temperature-measuring device provided on the surface of a wafer in a directly-heating oven controlled crystal oscillator according to the disclosure.

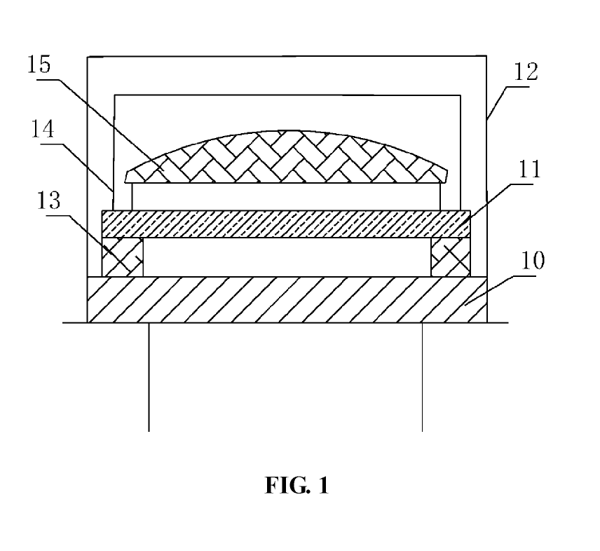

In FIG. 1:

10: T0-8 Base

11: Ceramic Substrate (on which Heating Circuit is provided)

12: T0-8 Upper Cover

13: Insulating Ring

14: Metal Housing

15: Quartz Wafer

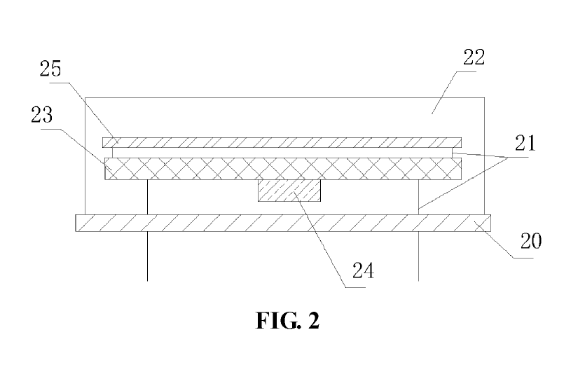

In FIG. 2:

20: T0-8 Base

21: Support Column

23: Ceramic Substrate (on which Control Circuit is provided)

24: Heat-Generating Device

25: Quartz Wafer

22: T0-8 Upper Cover

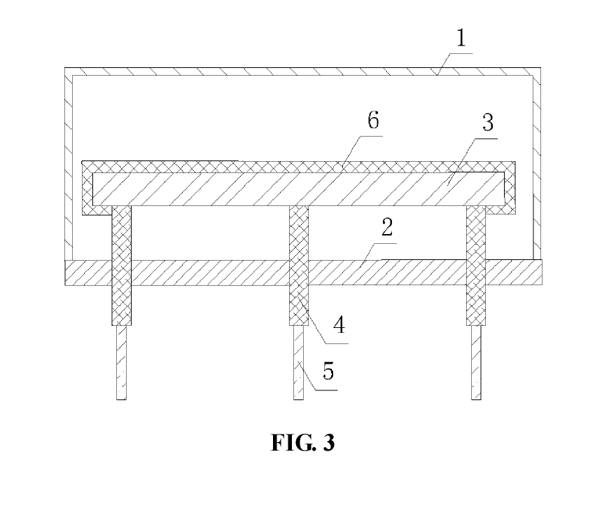

In FIG. 3 to FIG. 5

1: Upper Cover

2: Base

3: Quartz Wafer

4: Support Column

5: Crystal pin

6: Wire

61: First Wire End

62: Second Wire End

7: Temperature-Measuring Device

### DETAILED DESCRIPTION

For one skilled in the art to better understand the solutions of the disclosure, the solutions in the embodiments of the disclosure will be described clearly and fully below in conjunction with the drawings. Apparently, the embodiments described are only a part of the embodiments of the disclosure, rather than being the whole embodiments. All other embodiments obtained by one skilled in the art based on the embodiments in the disclosure without creative effort will pertain to the protection scope of disclosure.

FIG. 3 is a sectional view of a directly-heating oven controlled crystal oscillator according to the disclosure. Referring to FIG. 3, a directly-heating oven controlled crystal oscillator includes an upper cover 1, a base 2 and a wafer 3, the upper cover 1 is connected with the base 2 to form a mounting space for the wafer 3, the base 2 is provided with at least two support columns 4 penetrating through the base 2, one ends of the support columns 4 located inside the mounting space are connected to and support the wafer 3, and the other ends of the support columns 4 located outside the mounting space are connected to crystal pins 5, the surface of the wafer 3 is provided with a wire 6, and one end of the wire 6 is connected to the one end of one of the support columns 4 located inside the mounting space, and the other end of the wire 6 is connected to the one end of the other of the support columns 4 located inside the mounting space.

Preferably, the base 2 is provided with six support columns 4 penetrating through the base 2, the six support columns 4 are uniformly distributed on the base 2 and penetrate the base 2, and six crystal pins 5 are respectively extended out of the six support columns 4; the six crystal pins 5 are respectively a first grounding pin, a second grounding pin, a first crystal pin, a second crystal pin, a positive wire pin and a negative wire pin, wherein the first grounding pin and the second grounding pin are configured for grounding of the oven controlled crystal oscillator circuit, the first crystal pin and the second crystal pin are configured for acquiring the oscillation frequency of the crystal in the oven controlled crystal oscillator, and the positive wire pin and the negative wire pin are configured for applying a voltage and a current to the wire in the oven controlled crystal oscillator; the six crystal pins 5 may also be respectively a grounding pin, a powering pin, a frequency control pin, a frequency output pin, a positive wire pin and a negative wire pin, wherein the grounding pin is configured for grounding of the oven controlled crystal oscillator circuit, the powering pin is configured for powering the oven controlled crystal oscillator, the frequency control pin is configured for controlling the oscillation frequency of the oven controlled crystal oscillator, the frequency output pin is configured for acquiring and outputting the oscillation frequency of the oven controlled crystal oscillator, the positive wire pin and the negative wire pin are configured for apply a voltage and a current to the wire in the oven controlled crystal oscillator.

In the disclosure, the surface of the wafer 3 is provided with a wire 6, each of two ends of the wire 6 is connected to one end of a support column 4 located inside a mounting space, and the other end of the support column 4 located outside the mounting space is connected to a crystal pin 5. Accordingly, the wire 6 on the surface of the wafer is connected to an external circuit via the support column 4 and the crystal pin 5, that is, each of the two ends of the wire 6 is connected with a crystal pin 5, that is, the two ends of the wire 6 are connected with the positive wire pin and the negative wire pin, respectively. A voltage and a current are applied to the wire 6 via the positive wire pin and the negative wire pin, and hence the wafer 3 may be heated when the wire 6 generates heat.

In the oven controlled crystal oscillator according to the disclosure, no additional wafer-heating component needs to be assembled inside the crystal oscillator, and the wafer can be heated just by one-time plating a wire on the surface of the wafer; moreover, because the wire heats the wafer in a direct-contact manner, the part of power consumption used by an existing heat ceramic substrate in the process of transferring heat to the wafer may be saved, thereby lowering heating power consumption on the whole.

Preferably, platinum may be selected as the material of the wire in the disclosure. As a metal, the platinum wire has an electrical conductivity; the platinum wire still has another feature: the resistance of the platinum wire has a certain correspondence with the temperature of the platinum wire, that is, the platinum wire has a “resistance-temperature” correspondence list, so that the temperature of the platinum wire may be obtained by referring to the correspondence list when the resistance of the platinum wire is known. In the disclosure, by utilizing such a feature of the platinum wire, the platinum wire may not only be adapted to heat the wafer via conducting a current to generate heat, but also be adapted to measure the temperature of the wafer, so that it may be used as a multipurpose device for both heating and temperature-measuring. In the disclosure, by selecting platinum as the material of the wire, heating and temperature-measuring of the wafer may be implemented simultaneously.

### Embodiment 2

In the disclosure, a wire for heating the wafer is provided on the surface of the wafer. The wafer has a lower wafer surface close to the base and an upper wafer surface away from the base. In the disclosure, the arrangement manner of the wire is not limited, for example, a plurality of wires may be provided on the surface of the wafer, wherein the wires may be provided on the upper wafer surface, may be provided on the lower wafer surface, or may be provided on both the upper wafer surface and the lower wafer surface. The wire arrangement will be given in an embodiment below.

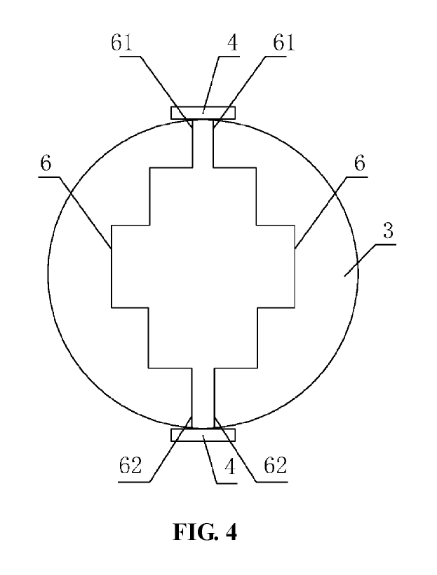

FIG. 4 is a top view of a wafer in a directly-heating oven controlled crystal oscillator according to the disclosure.

Referring to FIG. 4, the upper surface of the wafer 3 is provided with wires 6, and the number of the wires 6 is two. Each of the two wires 6 has a first wire end 61 and a second wire end 62 far from the first wire end, the first wire end 61 of each of the two wires 6 is connected to one end of one support column 4 located inside the mounting space, and the second wire end 62 of the each wire 6 is connected to one end of the other support column 4 located inside the mounting space. Thus, two wires 6 are provided in the manner shown in FIG. 4, and the two wires 6 are connected in parallel on the circuit.

Similarly, the two wires 6 may both be provided on the lower wafer surface, that is, the lower surface of the wafer 3 is provided with wires 6, and the number of the wire 6 is two. Each of the two wires 6 has a first wire end 61 and a second wire end 62 far from the first wire end, the first wire end 61 of each of the two wires 6 is connected to one end of one support column 4 located inside the mounting space, and the second wire end 62 of the each wire 6 is connected to one end of the other support column 4 located inside the mounting space. In such an arrangement manner, the two wires 6 are connected in parallel on the circuit.

Similarly, the two wires 6 may be respectively provided on the lower wafer surface and the upper wafer surface, that is, the lower surface of the wafer 3 is provided with one of the wires 6, and the upper surface of the wafer 3 is provided with the other of the wires 6, wherein each of the two wires 6 has a first wire end 61 and a second wire end 62 far from the first wire end, the first wire end 61 of each of the two wires 6 is connected to one end of one support column 4 located inside the mounting space, and the second wire end 62 of the each wire 6 is connect to one end of the other support column 4 located inside the mounting space. In such an arrangement manner, the two wires 6 are connected in parallel on the circuit.

However, a plurality of wires, such as 3 wires or 4 wires, etc., may also be provided on the surface of the wafer, which is not limited in the disclosure.

In the disclosure, the wire may be provided on the surface of the wafer via plating or in other manners, which is not limited in the disclosure.

In the oven controlled crystal oscillator according to the disclosure, the wire is provided the surface of the wafer once, and when a voltage and a current are applied to the wire, the wire generates heat and heats the wafer in a direct-contact manner. In the disclosure, no additional wafer-heating component needs to be assembled inside the crystal oscillator, and moreover, because the wire heats the wafer in a direct-contact manner, the part of power consumption used by an existing heat ceramic substrate in the process of transferring heat to the wafer may be saved, thereby lowering heating power consumption on the whole.

### Embodiment 3

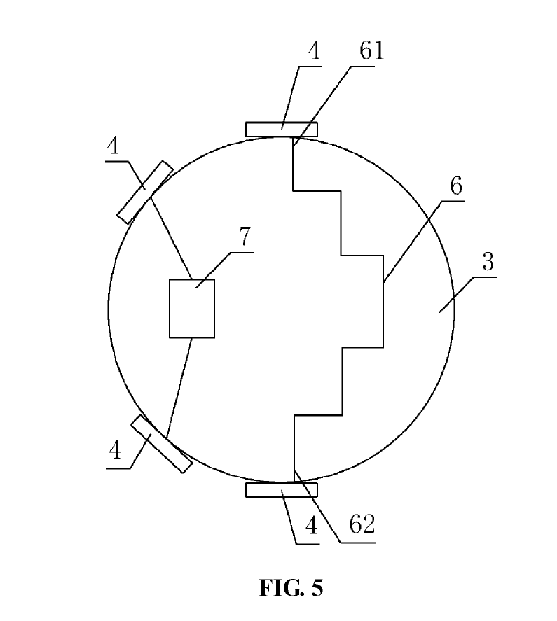

FIG. 5 is a top view of a temperature-measuring device further provided on the surface of a wafer in a directly-heating oven controlled crystal oscillator according to the disclosure.

In the disclosure, a temperature-measuring device may be provided on the surface of the wafer, and the temperature-measuring device may be arranged on the upper wafer surface or on the lower wafer surface.

Referring to FIG. 5, the upper surface of the wafer 3 is provided with a wire 6 and a temperature-measuring device 7. The wire 6 has a first wire end 61 and a second wire end 62 far from the first wire end, the first wire end 61 of the wire 6 is connected to one end of one support column 4 located inside the mounting space, and the second wire end 62 of the wire 6 is connected to one end of the other support column 4 located inside the mounting space. The temperature-measuring device 7 is connected to two support columns 4 that are not connected with the wire 6, so that the temperature-measuring device 7 is electrically connected with the support column 4, and one end of the support column 4 located outside the mounting space is connected to a crystal pin, and thus the temperature-measuring device 7 may be connected to an external circuit by means of the support column and the crystal pin, thereby realizing the measurement of the temperature of the wafer. The temperature-measuring device 7 may be a temperature sensor or a thermistor. For example, in the case that the temperature-measuring device 7 is a thermistor, the temperature of the wafer may be measured by detecting the resistance of the thermistor.

In the disclosure, the temperature-measuring device is provided on the surface of the wafer, so that the measurement of the temperature of the wafer may be realized; and hence the accuracy of the measurement of the temperature of the wafer may be improved by providing the temperature-measuring device on the surface of the wafer.

In summary, in the directly-heating oven controlled crystal oscillator according to the disclosure, a wire is provided on the surface of the wafer, and when a voltage and a current are applied to the wire, the wire generates heat and heats the wafer in a direct-contact manner. In the disclosure, no additional wafer-heating component needs to be assembled inside the crystal oscillator; moreover, because the wire heats the wafer in a direct-contact manner, the part of power consumption used by an existing heat ceramic substrate in the process of transferring heat to the wafer may be saved, thereby lowering heating power consumption on the whole. In the disclosure, the measurement of the temperature of the wafer may be realized by providing a temperature-measuring device on the surface of the wafer; and by providing the temperature-measuring device on the surface of the wafer, the accuracy of the measurement of the temperature of the wafer may be improved.

The principles of the disclosure have been described above in conjunction with specific embodiments. These descriptions are merely provided to explain the principles of the disclosure, rather than limiting the protection scope of the disclosure in any way. On the basis of the explanation herein, other embodiments may be obtained by one skilled in the art without creative effort, and all these embodiments will fall into the protection scope of the disclosure.

What is claimed is:

1. A directly-heating oven controlled crystal oscillator, comprising:
an upper cover, a base and a wafer,
wherein the upper cover is connected with the base to form a mounting space of the wafer, at least two support columns penetrating through the base are provided on the base, one ends of the support columns located inside the mounting space are connected to and support the wafer, and the other ends of the support columns located outside the mounting space are connected to crystal pins, and a surface of the wafer is provided with a wire, and
wherein one end of the wire is connected to the one end of one of the support columns located inside the mounting space, and the other end of the wire is connected to the one end of the other of the support columns located inside the mounting space.

2. The directly-heating oven controlled crystal oscillator according to claim 1, wherein the wire is made of a platinum material.

3. The directly-heating oven controlled crystal oscillator according to claim 1, wherein the number of the wires is two, and each of the two wires has a first wire end and a second wire end far from the first wire end, the first wire ends of the two wires are connected to the one end of one of the support columns located inside the mounting space, and the second wire ends of the two wires are connected to the one end of the other of the support columns located inside the mounting space.

4. The directly-heating oven controlled crystal oscillator according to claim 3, wherein, the wafer has a lower wafer surface close to the base and an upper wafer surface away from the base, and the two wires are both located on the upper wafer surface.

5. The directly-heating oven controlled crystal oscillator according to claim 3, wherein, the wafer has a lower wafer surface close to the base and an upper wafer surface facing away from the base, and the two wires are both located on the lower wafer surface.

6. The directly-heating oven controlled crystal oscillator according to claim 3, wherein, the wafer has a lower wafer surface close to the base and an upper wafer surface facing away from the base, and the two wires are located on the lower wafer surface and the upper wafer surface, respectively.

7. The directly-heating oven controlled crystal oscillator according to claim 1, wherein, the surface of the wafer is further provided with a temperature-measuring device, the temperature-measuring device is electrically connected with one end of the support column located inside the mounting space, and the support column connected with the temperature-measuring device is different from the support column connected with the wire.

8. The directly-heating oven controlled crystal oscillator according to claim 7, wherein, the temperature-measuring device is one of a temperature sensor and a thermistor.
